(19) United States
(12) Patent Application Publication
(10) Pub. No.: US 2026/0254561 A1
(43) Pub. Date: Aug. 27, 2026

(54) SYSTEM AND METHOD FOR FORWARD ERROR CORRECTION IN AN ON-BOARD PROCESSING SATELLITE TRANSPONDER

(71) Applicant: AYECKA COMMUNICATION SYSTEMS LTD., Kfar Saba (IL)

(72) Inventors: Sorin GOLDENBERG, Ness Ziona (IL); Avraham BARDA, Hod Hasharon (IL); Igal GERZBERG, Netanya (IL); Baruch KAGAN, Kiryat Ono (IL)

(21) Appl. No.: 19/161,532

(22) PCT Filed: Feb. 29, 2024
(86) PCT No.: PCT/IL2024/050228

§ 371 Date: Sep. 2, 2025

Related U.S. Application Data
(60) Provisional application No. 63/488,070, filed on Mar. 2, 2023.

(51) Int. Cl. H04L 1/00; H03M 13/03; H03M 13/11; H04B 7/185

(52) U.S. Cl. CPC H04L 1/0057; H03M 13/036; H03M 13/1111; H04L 1/0041; H04L 1/0045; H04B 7/18513

(57) ABSTRACT

A forward error correction (EEC) system and method are provided, intended for DVB-S2 data streams in an on-board processing transponder of a LEO communication satellite. The system comprises an LDPC encoder circuit implemented in an FPGA, and a terrestrial cellular network compatible soft-decision-EEC (SD-FEC) LDPC decoder module, implemented in an AS IC module which is embedded in the FPGA.

### FIELD OF THE INVENTION

The present invention relates generally to low-density parity-check (LDPC) forward error correction (FEC), and more particularly to LDPC embodiments in low-earth-orbit (LEO) Satellite transponders.

### BACKGROUND OF THE INVENTION

There is an increasing demand to provide data services for isolated, possibly mobile, end points over the globe. LEO satellite networks have become a cost-effective solution for this demand due to various limitations and drawbacks of alternative solutions provided by Geostationary Equatorial Orbit (GEO) satellites. DVB-S2 standard is commonly used in data services provided through satellites and necessitates a suitable LDPC FEC solution. The implementation in LEO satellite imposes strict constraints on such a solution with respect to power consumption and compliance with harsh environmental conditions. These constrains severely impact the ability to produce a cost-effective application-specific integrated circuit (ASIC) based LDPC solution. Therefore, there is a clear need in the market for a field-programmable gate array (FPGA) based LDPC implementation for data services through LEO satellites.

### SUMMARY OF THE INVENTION

Accordingly, it is a principal object of the present invention to provide an FPGA based FEC system, intended for DVB-S2 data streams in an on-board processing (OBP) transponder of LEO communication satellites. The system disclosed herein comprises, within the FPGA, an LDPC encoder circuit for encoding data directed to one or more earth stations that are included in a satellite-based data communication network. The FPGA also contains a soft-decision-FEC (SD-FEC) LDPC decoder module for decoding data streams received from the network earth stations. This module is implemented in ASIC technology within the FPGA. The SD-FEC module is a commercial product that is commonly used to decode LDPC encoded data streams in cellular networks. The FPGA also contains an outer concatenated Bose-Chaudhuri-Hocquenghem (BCH) code for achieving close to zero bit-error-rate (BER) when the LDPC code provides sufficiently low BER.

In typical embodiments, the LDPC decoder module is configured to decode LDPC encoded upstream data using a parity check matrix that is partitioned to 360×360 bit sub-matrices such that each sub-matrix is either a zero matrix, an identity matrix or a shifted diagonal identity matrix. A diagonal is shifted such that its part that is pushed out of its submatrix in one side thereof is cyclically folded back into the submatrix at its other side.

In some embodiments, the network includes more than a single LEO satellite. In such networks, transponder transmit data may be directed to another satellite, and receive data may as well arrive from another satellite.

In one embodiment, for achieving maximum coding gain with coding rate 1/4, the SD-FEC LDPC decoder module is configured such that its parity check sub-matrices containing diagonals are arranged according to the list below. Each line in the list represents a respective row of sub-matrices in the parity check matrix, and each pair of numbers within each line corresponds to a sub-matrix within the row such that the first number in the pair indicates the sub-matrix ordinal number in the row, and the second number indicates the shift of the sub-matrix diagonal from the diagonal location in an identity matrix of the same order:
1) 2,162; 9,85; 10,0;
2) 2,172; 4,249; 10,0; 11,0;
3) 5,268; 11,0; 12,0;
4) 1,254; 4,195; 12,0; 13,0;
5) 1,247; 3,128; 13,0; 14,0;
6) 6,40; 14,0; 15,0;
7) 1,306; 3,74; 15,0; 16,0;
8) 4,212; 7,278; 16,0; 17,0;
9) 1,204; 3,48; 17,0; 18,0;
10) 3,220; 8,303; 18,0; 19,0;
11) 1,75; 3,342; 19,0; 20,0;
12) 1,23; 20,0; 21,0;
13) 4,254; 9,32; 21,0; 22,0;
14) 5,184; 9,247; 22,0; 23,0;
15) 2,278; 6,251; 23,0; 24,0;
16) 1,60; 4,243; 24,0; 25,0;
17) 1,15; 8,308; 25,0; 26,0;
18) 3,118; 4,161; 26,0; 27,0;
19) 2,204; 7,87; 27,0; 28,0;
20) 1,301; 4,314; 28,0; 29,0;
21) 2,79; 7,268; 29,0; 30,0;
22) 4,57; 30,0; 31,0;
23) 2,249; 3,64; 31,0; 32,0;
24) 5,358; 32,0; 33,0;
25) 4,179; 8,32; 33,0; 34,0;
26) 2,180; 6,303; 34,0; 35,0;
27) 1,266; 4,344; 35,0; 36,0;
28) 3,237; 36,0; 37,0;
29) 2,79; 37,0; 38,0;
30) 2,250; 3,269; 38,0; 39,0;
31) 4,346; 39,0; 40,0;
32) 1,133; 3,251; 40,0; 41,0;
33) 1,341; 41,0; 42,0;
34) 2,3; 4,102; 42,0; 43,0;
35) 2,46; 3,71; 43,0; 44,0;
36) 2,344; 3,46; 44,0; 45,0.

In one embodiment, for achieving maximum coding gain with coding rate 1/2, the SD-FEC LDPC decoder module is configured as explained above for coding rate 1/4, while the above list is replaced by the following one:
1) 1,346; 3,184; 8,116; 9,133; 19,113; 21,0;
2) 6,209; 7,159; 11,239; 14,269; 21,0; 22,0;
3) 1,33; 2,201; 10,35; 16,124; 22,0; 23,0;
4) 1,155; 5,7; 9,151; 23,0; 24,0;
5) 2,327; 5,122; 20,216; 24,0; 25,0;
6) 3,280; 4,246; 14,181; 18,292; 25,0; 26,0;
7) 1,197; 5,254; 12,204; 17,293; 26,0; 27,0;
8) 5,138; 8,91; 15,144; 16,316; 27,0; 28,0;
9) 6,235; 7,228; 17,196; 19,58; 28,0; 29,0;
10) 2,284; 3,52; 11,160; 16,274; 29,0; 30,0;
11) 2,176; 3,108; 14,95; 15,231; 30,0; 31,0;
12) 4,46; 6,170; 13,297; 20,154; 31,0; 32,0;
13) 1,265; 4,81; 11,186; 14,306; 32,0; 33,0;
14) 1,72; 3,213; 10,76; 18,160; 33,0; 34,0;
15) 8,260; 12,183; 15,204; 17,118; 34,0; 35,0;
16) 7,284; 8,246; 16,286; 18,283; 35,0; 36,0;
17) 1,347; 2,179; 10,164; 19,196; 36,0; 37,0;
18) 1,49; 2,230; 10,296; 13,46; 37,0; 38,0;
19) 3,70; 4,262; 13,68; 18,358; 38,0; 39,0;
20) 2,215; 3,308; 12,342; 13,227; 39,0; 40,0;
21) 2,265; 7,54; 9,269; 19,135; 40,0; 41,0;
22) 2,83; 3,257; 12,15; 20,292; 41,0; 42,0;
23) 1,31; 3,95; 20,158; 42,0; 43,0;
24) 2,205; 3,175; 9,156; 15,228; 43,0; 44,0;
25) 1,137; 6,102; 11,329; 17,109; 44,0; 45,0.

In one embodiment, for achieving maximum coding gain with coding rate 3/4, the SD-FEC LDPC decoder module is configured as explained above for coding rate 1/4, while the above list is replaced by the following one:
1) 1,185; 4,50; 7,337; 8,4; 9,246; 11,80; 14,253; 16,300; 20,308; 22,84; 26,23; 29,244; 33,14; 34,0;
2) 1,152; 2,97; 6,332; 8,184; 10,135; 15,307; 16,199; 23,236; 24,234; 27,4; 28,346; 34,0; 35,0;
3) 1,27; 2,279; 6,27; 9,42; 12,343; 15,347; 17,211; 21,39; 25,342; 27,150; 28,354; 35,0; 36,0;
4) 1,232; 3,38; 5,61; 8,52; 10,339; 18,231; 19,123; 21,257; 24,254; 29,308; 30,301; 36,0; 37,0;
5) 1,88; 2,325; 5,351; 11,288; 13,170; 19,91; 21,301; 25,225; 27,248; 29,315; 30,53; 33,215; 37,0; 38,0;
6) 1,334; 3,205; 6,217; 9,196; 12,49; 14,192; 18,318; 23,172; 24,55; 26,304; 28,24; 32,115; 38,0; 39,0;
7) 1,352; 3,50; 7,214; 8,288; 10,243; 14,297; 19,77; 20,137; 25,29; 26,357; 29,52; 32,154; 39,0; 40,0;
8) 1,309; 3,15; 5,29; 13,10; 15,2; 17,10; 19,355; 20,355; 22,41; 31,115; 33,259; 40,0; 41,0;
9) 1,213; 4,51; 5,91; 9,69; 10,113; 16,24; 17,238; 21,160; 23,260; 30,144; 31,343; 32,149; 41,0; 42,0;
10) 1,281; 4,205; 7,289; 11,253; 12,63; 16,312; 17,147; 22,163; 24,159; 26,113; 31,83; 42,0; 43,0;
11) 1,290; 4,332; 7,55; 12,159; 13,66; 14,147; 18,325; 22,188; 23,234; 27,153; 31,86; 33,170; 43,0; 44,0;
12) 1,323; 2,304; 6,289; 11,119; 13,223; 15,246; 18,16; 20,286; 25,358; 28,309; 30,148; 32,22; 44,0; 45,0.

In one embodiment, for achieving maximum coding gain with coding rate 5/6, the SD-FEC LDPC decoder module is configured as explained above for coding rate 1/4, while the above list is replaced by the following one:
1) 2,121; 5,122; 6,326; 8,304; 9,165; 11,22; 14,331; 17,293; 20,287; 22,205; 26,115; 28,20; 31,221; 33,183; 35,14; 37,306; 38,0;
2) 3,215; 4,57; 7,176; 10,184; 11,237; 15,178; 21,262; 23,265; 25,312; 27,18; 30,77; 31,294; 35,269; 36,32; 37,4; 38,0; 39,0;
3) 2,212; 5,10; 7,82; 12,285; 16,224; 18,26; 20,321; 21,121; 23,73; 24,216; 26,52; 29,172; 30,80; 32,181; 34,329; 36,186; 39,0; 40,0; 1,33; 3,118; 8,57; 12,201; 13,203; 16,1; 18,272; 19,179; 22,285; 24,72; 26,287; 28,200; 30,135; 33,139; 35,239; 37,172; 40,0; 41,0;
4) 3,190; 4,155; 6,36; 10,108; 11,226; 15,356; 17,176; 19,221; 25,269; 26,273; 28,302; 29,254; 30,146; 33,33; 34,95; 36,325; 41,0; 42,0;
5) 1,48; 4,57; 7,210; 9,353; 13,205; 15,44; 17,337; 20,61; 23,89; 24,159; 27,255; 29,135; 31,89; 32,194; 35,116; 36,181; 42,0; 43,0;
6) 1,178; 8,335; 10,354; 12,271; 14,103; 16,120; 21,148; 23,27; 24,316; 25,109; 27,307; 29,339; 32,210; 33,281; 34,175; 37,222; 43,0; 44,0;
7) 2,241; 5,106; 6,329; 9,155; 13,350; 14,355; 18,303; 19,266; 22,355; 25,86; 27,348; 28,174; 31,354; 32,234; 34,203; 44,0; 45,0.

In embodiments of the present invention, also a method for achieving maximum coding gain while receiving DVB-S2 protocol data in a LEO communication satellite is disclosed. The method relates to soft-decision FEC (SD-FEC) LDPC decoder implemented in an ASIC module within an FPGA comprising FEC encoder and decoder that process DVB-S2 data as described above. The method comprises configuring the SD-FEC so as to apply to the received data a parity check matrix composed of 360×360 bit sub-matrices such that each sub-matrix is either a zero matrix, an identity matrix or a shifted diagonal identity matrix. For achieving maximum coding gain with coding rate 1/4, for example, the SD-FEC LDPC decoder module is configured such that the sub-matrices that contain diagonals are arranged according to the following list, in which, each line represents a respective row of sub-matrices in the parity check matrix, and each pair of numbers within said each line corresponds to a sub-matrix within said respective parity check matrix row such that the first number in the pair indicates the sub-matrix ordinal number in the row and the second number indicates the shift of the sub-matrix diagonal from the diagonal location in an identity matrix of the same order. A diagonal is shifted such that its part that is pushed out of its submatrix in one side thereof is cyclically folded back into the submatrix at its other side:
1) 2,162; 9,85; 10,0;
2) 2,172; 4,249; 10,0; 11,0;
3) 5,268; 11,0; 12,0;
4) 1,254; 4,195; 12,0; 13,0;
5) 1,247; 3,128; 13,0; 14,0;
6) 6,40; 14,0; 15,0;
7) 1,306; 3,74; 15,0; 16,0;
8) 4,212; 7,278; 16,0; 17,0;
9) 1,204; 3,48; 17,0; 18,0;
10) 3,220; 8,303; 18,0; 19,0;
11) 1,75; 3,342; 19,0; 20,0;
12) 1,23; 20,0; 21,0;
13) 4,254; 9,32; 21,0; 22,0;
14) 5,184; 9,247; 22,0; 23,0;
15) 2,278; 6,251; 23,0; 24,0;
16) 1,60; 4,243; 24,0; 25,0;
17) 1,15; 8,308; 25,0; 26,0;
18) 3,118; 4,161; 26,0; 27,0;
19) 2,204; 7,87; 27,0; 28,0;
20) 1,301; 4,314; 28,0; 29,0;
21) 2,79; 7,268; 29,0; 30,0;
22) 4,57; 30,0; 31,0;
23) 2,249; 3,64; 31,0; 32,0;
24) 5,358; 32,0; 33,0;
25) 4,179; 8,32; 33,0; 34,0;
26) 2,180; 6,303; 34,0; 35,0;
27) 1,266; 4,344; 35,0; 36,0;
28) 3,237; 36,0; 37,0;
29) 2,79; 37,0; 38,0;
30) 2,250; 3,269; 38,0; 39,0;
31) 4,346; 39,0; 40,0;
32) 1,133; 3,251; 40,0; 41,0;
33) 1,341; 41,0; 42,0;
34) 2,3; 4,102; 42,0; 43,0;
35) 2,46; 3,71; 43,0; 44,0;
36) 2,344; 3,46; 44,0; 45,0.

The disclosed method allows achieving maximum coding gain with various coding rates. Configuration lists that correspond to coding rates other than 1/4 are provided above in relation with the corresponding system embodiments.

### BRIEF DESCRIPTION OF THE DRAWINGS

The present invention will be more fully understood from the following detailed description of the embodiments thereof, taken together with the drawing in which:

FIG. 1A is a block diagram that schematically illustrates an on-board processing satellite transponder, in accordance with an embodiment of the present invention;

FIG. 1B is a block diagram that schematically illustrates a LEO satellite network, in accordance with an embodiment of the present invention;

FIG. 2 is a flowchart illustrating method steps for LDPC soft-decision configuration, in accordance with an embodiment of the present invention; and

FIGS. 3A to 3D are plots illustrating Es/No performance results for various coding rates, in accordance with an embodiment of the present invention.

### DETAILED DESCRIPTION OF EMBODIMENTS

Embodiments of the present invention provide a cost-effective FPGA based FEC system for OBP transponders in LEO satellites, wherein the transponders serve as DVB-S2 based regenerative and switching repeaters for terrestrial data networks.

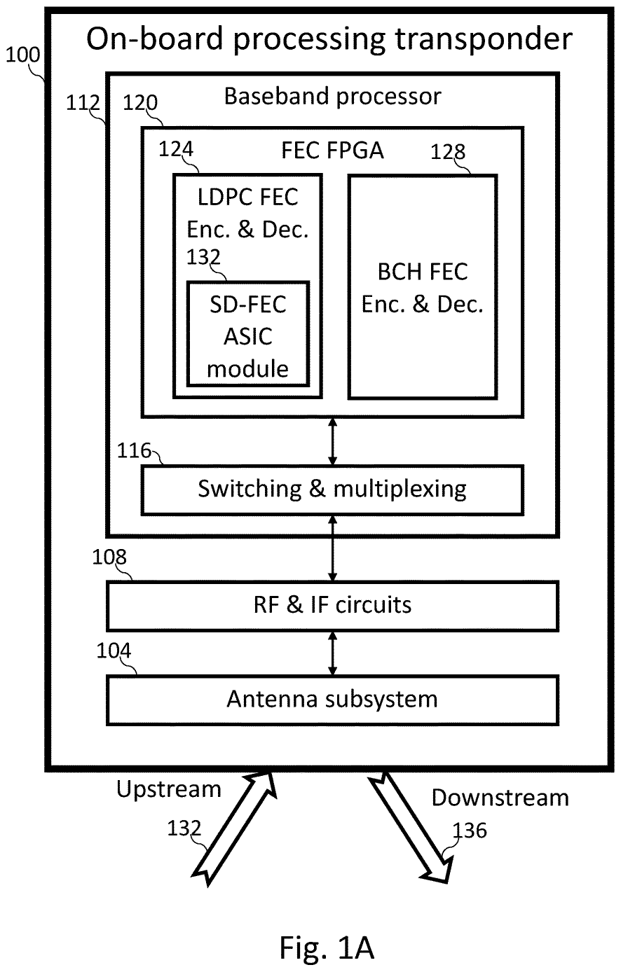

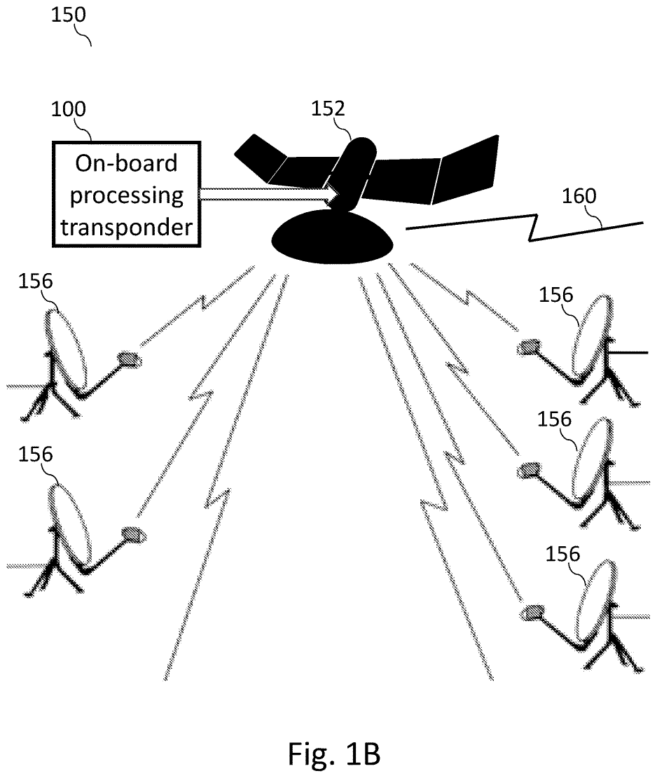

Referring to FIG. 1A, there is shown a block diagram of an OBP transponder 100 that processes receive and transmit DVB-S2 based data streams, in accordance with an embodiment of the present invention. The transponder contains an antenna front end subsystem 104, RF and IF circuitry 108 and a baseband processor 112. Processor 112 is a baseband data processing module whose main functions are herein explained.

Module 116 mainly implements DVB-S2 functions that relate to data streams arrived from and sent to satellite earth terminals, such as modulation/demodulation, switching data between the terminals and demultiplexing/multiplexing data units related the various terminals. The DVB-S2 FEC function is implemented in a FEC FPGA 120. FPGA 120 comprises an LDPC encoder and decoder block 124 and an outer concatenated BCH encoder and decoder block 128. the LDPC soft decoding is implemented in an SD-FEC ASIC module 132 that is embedded in FEC FPGA 120. Module 132 performs the decoding using a parity check matrix whose all non-zero sub-matrices are structured as explained hereinafter.

Transponder 100 communicates with earth terminals in radio frequency bands such as Ku and Ka. The radio waves arrived from and sent to the earth terminals are represented in FIG. 1A by upstream and downstream arrows indicated by reference numerals 132 and 136 respectfully. However, the disclosed techniques are also applicable to networks that comprise inter-satellite communication, which is not shown in FIG. 1A.

FIG. 1B illustrates a LEO satellite data network 150, in accordance with an embodiment of the present invention. The network includes a LEO satellite 152, which contains the aforementioned OBP transponder 100. Satellite 152 processes and passes point-to-point and point-to-multipoint traffic between a plurality of earth terminals 156. In some embodiments, satellite 152 may use one or more radio links 160 to communicate LDPC encoded/decoded OBP traffic with respective one or more other LEO satellites (not shown in FIG. 1B).

Various multiple access techniques may be employed in embodiments of the present invention. In one embodiment, frequency division multiple access (FDMA) is employed in the uplink and statistical multiplexing is employed in the downlink.

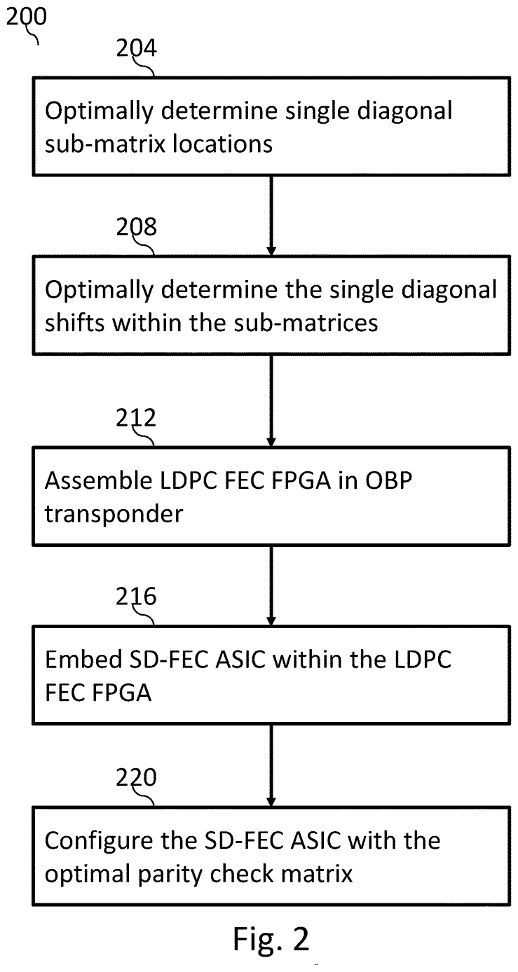

Referring now to FIG. 2, there is shown a flowchart 200 illustrating LDPC soft-decision configuration method steps, in accordance with an embodiment of the present invention. The method begins with steps 204 and 208, in which the locations of the single diagonal sub-matrices in the SD-FEC parity check matrix, and their diagonal shifts within the sub-matrices, are respectively optimally determined as explained hereinafter. Next, in an assembling step 212, LDPC FEC FPGA 120 is assembled in OBP transponder 100. In step 216 that follows, SD-FEC ASIC 132 is embedded within LDPC FEC FPGA 120. Flowchart 200 then ends with step 220, in which SD-FEC ASIC 132 is programmed with the optimal parity check matrix, as determined by previous steps 204 and 208.

The SD-FEC parity check matrix structure in system and method embodiments as per the present invention is explained in the following. The parity check matrix is partitioned to 360×360 bit sub-matrices such that each sub-matrix is either a zero matrix, an identity matrix or a shifted diagonal identity matrix. A diagonal is shifted such that its part that is pushed out of its submatrix in one side thereof is cyclically folded back into the submatrix at its other side.

In one embodiment, for achieving maximum coding gain with coding rate 1/4, the SD-FEC LDPC decoder module is configured such that its parity check sub-matrices containing diagonals are arranged according to the list below. Each line in the list represents a respective row of sub-matrices in the parity check matrix, and each pair of numbers within each line corresponds to a sub-matrix within the row such that the first number in the pair indicates the sub-matrix ordinal number in the row, and the second number indicates the shift of the sub-matrix diagonal from the diagonal location in an identity matrix of the same order:
1) 2,162; 9,85; 10,0;
2) 2,172; 4,249; 10,0; 11,0;
3) 5,268; 11,0; 12,0;
4) 1,254; 4,195; 12,0; 13,0;
5) 1,247; 3,128; 13,0; 14,0;
6) 6,40; 14,0; 15,0;
7) 1,306; 3,74; 15,0; 16,0;
8) 4,212; 7,278; 16,0; 17,0;
9) 1,204; 3,48; 17,0; 18,0;
10) 3,220; 8,303; 18,0; 19,0;
11) 1,75; 3,342; 19,0; 20,0;
12) 1,23; 20,0; 21,0;
13) 4,254; 9,32; 21,0; 22,0;
14) 5,184; 9,247; 22,0; 23,0;
15) 2,278; 6,251; 23,0; 24,0;
16) 1,60; 4,243; 24,0; 25,0;
17) 1,15; 8,308; 25,0; 26,0;
18) 3,118; 4,161; 26,0; 27,0;
19) 2,204; 7,87; 27,0; 28,0;
20) 1,301; 4,314; 28,0; 29,0;
21) 2,79; 7,268; 29,0; 30,0;
22) 4,57; 30,0; 31,0;
23) 2,249; 3,64; 31,0; 32,0;
24) 5,358; 32,0; 33,0;
25) 4,179; 8,32; 33,0; 34,0;
26) 2,180; 6,303; 34,0; 35,0;
27) 1,266; 4,344; 35,0; 36,0;
28) 3,237; 36,0; 37,0;
29) 2,79; 37,0; 38,0;
30) 2,250; 3,269; 38,0; 39,0;
31) 4,346; 39,0; 40,0;
32) 1,133; 3,251; 40,0; 41,0;
33) 1,341; 41,0; 42,0;
34) 2,3; 4,102; 42,0; 43,0;
35) 2,46; 3,71; 43,0; 44,0;
36) 2,344; 3,46; 44,0; 45,0.

In one embodiment, for achieving maximum coding gain with coding rate 1/2, the SD-FEC LDPC decoder module is configured as explained above for coding rate 1/4, while the above list is replaced by the following one:
1) 1,346; 3,184; 8,116; 9,133; 19,113; 21,0;
2) 6,209; 7,159; 11,239; 14,269; 21,0; 22,0;
3) 1,33; 2,201; 10,35; 16,124; 22,0; 23,0;
4) 1,155; 5,7; 9,151; 23,0; 24,0;
5) 2,327; 5,122; 20,216; 24,0; 25,0;
6) 3,280; 4,246; 14,181; 18,292; 25,0; 26,0;
7) 1,197; 5,254; 12,204; 17,293; 26,0; 27,0;
8) 5,138; 8,91; 15,144; 16,316; 27,0; 28,0;
9) 6,235; 7,228; 17,196; 19,58; 28,0; 29,0;
10) 2,284; 3,52; 11,160; 16,274; 29,0; 30,0;
11) 2,176; 3,108; 14,95; 15,231; 30,0; 31,0;
12) 4,46; 6,170; 13,297; 20,154; 31,0; 32,0;
13) 1,265; 4,81; 11,186; 14,306; 32,0; 33,0;
14) 1,72; 3,213; 10,76; 18,160; 33,0; 34,0;
15) 8,260; 12,183; 15,204; 17,118; 34,0; 35,0;
16) 7,284; 8,246; 16,286; 18,283; 35,0; 36,0;
17) 1,347; 2,179; 10,164; 19,196; 36,0; 37,0;
18) 1,49; 2,230; 10,296; 13,46; 37,0; 38,0;
19) 3,70; 4,262; 13,68; 18,358; 38,0; 39,0;
20) 2,215; 3,308; 12,342; 13,227; 39,0; 40,0;
21) 2,265; 7,54; 9,269; 19,135; 40,0; 41,0;
22) 2,83; 3,257; 12,15; 20,292; 41,0; 42,0;
23) 1,31; 3,95; 20,158; 42,0; 43,0;
24) 2,205; 3,175; 9,156; 15,228; 43,0; 44,0;
25) 1,137; 6,102; 11,329; 17,109; 44,0; 45,0.

In one embodiment, for achieving maximum coding gain with coding rate 3/4, the SD-FEC LDPC decoder module is configured as explained above for coding rate 1/4, while the above list is replaced by the following one:
1) 1,185; 4,50; 7,337; 8,4; 9,246; 11,80; 14,253; 16,300; 20,308; 22,84; 26,23; 29,244; 33,14; 34,0;
2) 1,152; 2,97; 6,332; 8,184; 10,135; 15,307; 16,199; 23,236; 24,234; 27,4; 28,346; 34,0; 35,0;
3) 1,27; 2,279; 6,27; 9,42; 12,343; 15,347; 17,211; 21,39; 25,342; 27,150; 28,354; 35,0; 36,0;
4) 1,232; 3,38; 5,61; 8,52; 10,339; 18,231; 19,123; 21,257; 24,254; 29,308; 30,301; 36,0; 37,0;
5) 1,88; 2,325; 5,351; 11,288; 13,170; 19,91; 21,301; 25,225; 27,248; 29,315; 30,53; 33,215; 37,0; 38,0;
6) 1,334; 3,205; 6,217; 9,196; 12,49; 14,192; 18,318; 23,172; 24,55; 26,304; 28,24; 32,115; 38,0; 39,0;
7) 1,352; 3,50; 7,214; 8,288; 10,243; 14,297; 19,77; 20,137; 25,29; 26,357; 29,52; 32,154; 39,0; 40,0;
8) 1,309; 3,15; 5,29; 13,10; 15,2; 17,10; 19,355; 20,355; 22,41; 31,115; 33,259; 40,0; 41,0;
9) 1,213; 4,51; 5,91; 9,69; 10,113; 16,24; 17,238; 21,160; 23,260; 30,144; 31,343; 32,149; 41,0; 42,0;
10) 1,281; 4,205; 7,289; 11,253; 12,63; 16,312; 17,147; 22,163; 24,159; 26,113; 31,83; 42,0; 43,0;
11) 1,290; 4,332; 7,55; 12,159; 13,66; 14,147; 18,325; 22,188; 23,234; 27,153; 31,86; 33,170; 43,0; 44,0;
12) 1,323; 2,304; 6,289; 11,119; 13,223; 15,246; 18,16; 20,286; 25,358; 28,309; 30,148; 32,22; 44,0; 45,0.

In one embodiment, for achieving maximum coding gain with coding rate 5/6, the SD-FEC LDPC decoder module is configured as explained above for coding rate 1/4, while the above list is replaced by the following one:
1) 2,121; 5,122; 6,326; 8,304; 9,165; 11,22; 14,331; 17,293; 20,287; 22,205; 26,115; 28,20; 31,221; 33,183; 35,14; 37,306; 38,0;
2) 3,215; 4,57; 7,176; 10,184; 11,237; 15,178; 21,262; 23,265; 25,312; 27,18; 30,77; 31,294; 35,269; 36,32; 37,4; 38,0; 39,0;
3) 2,212; 5,10; 7,82; 12,285; 16,224; 18,26; 20,321; 21,121; 23,73; 24,216; 26,52; 29,172; 30,80; 32,181; 34,329; 36,186; 39,0; 40,0; 1,33; 3,118; 8,57; 12,201; 13,203; 16,1; 18,272; 19,179; 22,285; 24,72; 26,287; 28,200; 30,135; 33,139; 35,239; 37,172; 40,0; 41,0;
4) 3,190; 4,155; 6,36; 10,108; 11,226; 15,356; 17,176; 19,221; 25,269; 26,273; 28,302; 29,254; 30,146; 33,33; 34,95; 36,325; 41,0; 42,0;
5) 1,48; 4,57; 7,210; 9,353; 13,205; 15,44; 17,337; 20,61; 23,89; 24,159; 27,255; 29,135; 31,89; 32,194; 35,116; 36,181; 42,0; 43,0;
6) 1,178; 8,335; 10,354; 12,271; 14,103; 16,120; 21,148; 23,27; 24,316; 25,109; 27,307; 29,339; 32,210; 33,281; 34,175; 37,222; 43,0; 44,0;
7) 2,241; 5,106; 6,329; 9,155; 13,350; 14,355; 18,303; 19,266; 22,355; 25,86; 27,348; 28,174; 31,354; 32,234; 34,203; 44,0; 45,0.

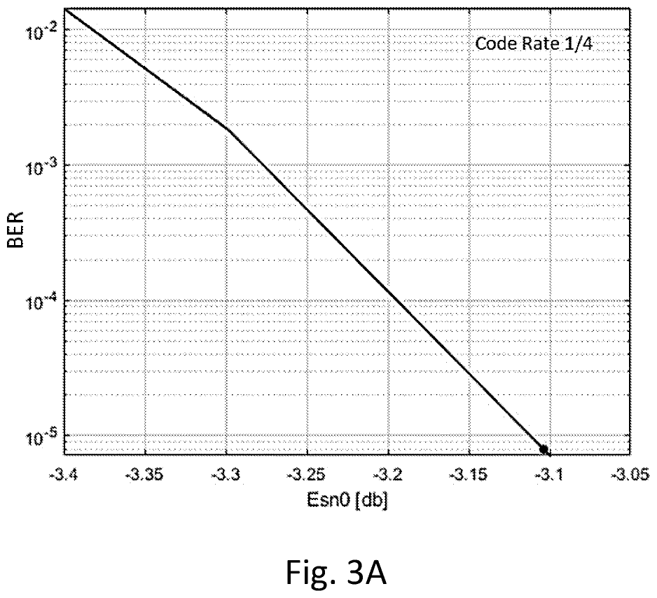

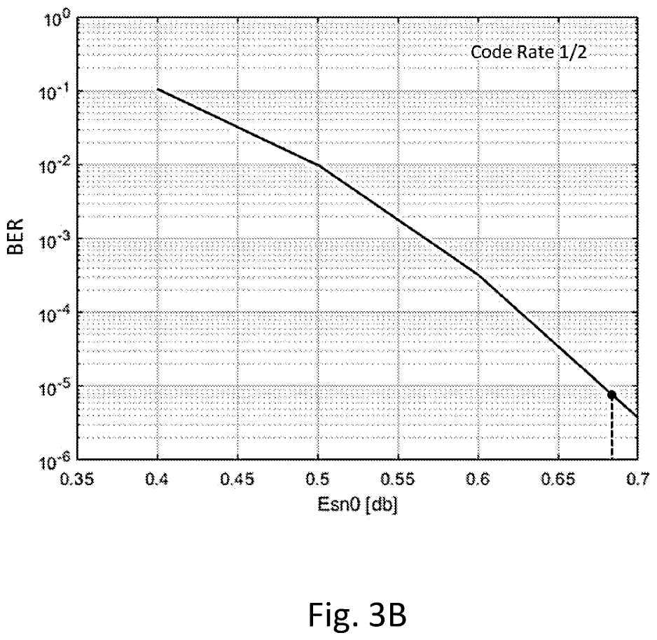

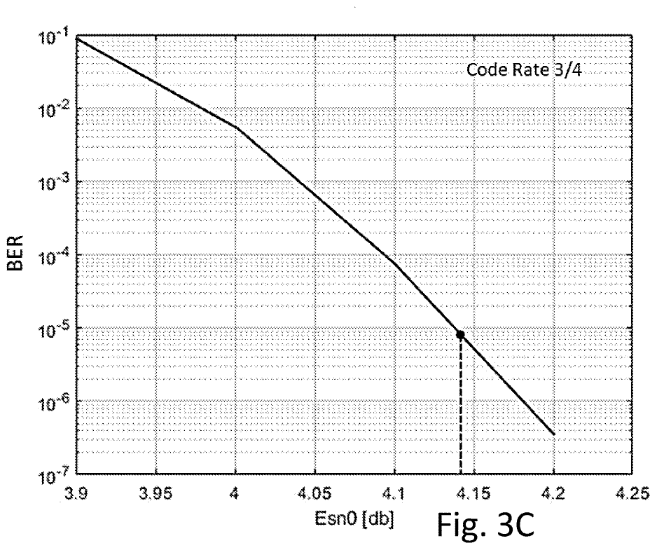

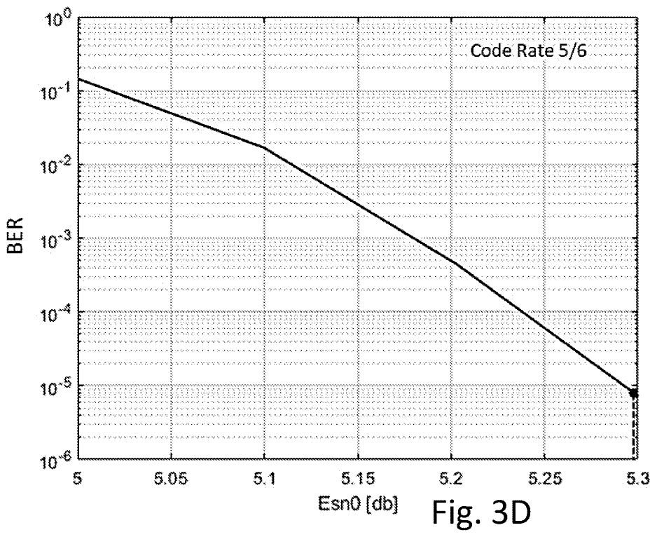

Finally, FIGS. 3A to 3D illustrate graphs of bit error rate (BER) obtained as a function of symbol energy to noise density (Es/No), for coding rates 1/4, 1/2, 3/4 and 5/6 respectively. Referring, for example, to a reference BER of 8*10E−6, the graphs show that reducing the coding rate from 5/6 to 1/4 allows decreasing the required Es/No from 5.3 dB to −3.1 dB. This decrease represents a coding gain of 8.4 dB.

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art.

1. A forward error correction (FEC) system, intended for processing DVB-S2 protocol data streams in an on-board processing (OBP) transponder of a low-earth-orbit (LEO) communication satellite, the system comprising:
a low-density parity-check (LDPC) encoder circuit implemented in a field programable gate array (FPGA) within the OBP transponder and configured to encode data directed to one or more earth stations; and
a cellular network compatible soft-decision-FEC (SD-FEC) LDPC decoder module, implemented in an application-specific integrated circuit (ASIC) module, which is embedded in said FPGA, and configured to decode data received by the OBP transponder from said one or more earth stations.

2. The system of claim 1, wherein the LDPC encoder is also configured to encode data directed to another satellite.

3. The system of claim 1, wherein the LDPC decoder is also configured to decode data received by the OBP transponder from another satellite.

4. The system of claim 1, wherein the SD-FEC LDPC decoder module is configured to apply to the received data a parity check matrix composed of 360×360 bit sub-matrices such that each sub-matrix is either a zero matrix, an identity matrix or a shifted diagonal identity matrix.

5. The system of claim 4, wherein, for achieving maximum coding gain with coding rate 1/4, the SD-FEC LDPC decoder module is configured such that the sub-matrices that contain diagonals are arranged according to the following list, in which, each line represents a respective row of sub-matrices in the parity check matrix, and each pair of numbers within said each line corresponds to a sub-matrix within said respective parity check matrix row such that the first number in the pair indicates the sub-matrix ordinal number in the row and the second number indicates the shift of the sub-matrix diagonal from the diagonal location in an identity matrix of the same order:
1) 2,162; 9,85; 10,0;
2) 2,172; 4,249; 10,0; 11,0;
3) 5,268; 11,0; 12,0;
4) 1,254; 4,195; 12,0; 13,0;
5) 1,247; 3,128; 13,0; 14,0;
6) 6,40; 14,0; 15,0;
7) 1,306; 3,74; 15,0; 16,0;
8) 4,212; 7,278; 16,0; 17,0;
9) 1,204; 3,48; 17,0; 18,0;
10) 3,220; 8,303; 18,0; 19,0;
11) 1,75; 3,342; 19,0; 20,0;
12) 1,23; 20,0; 21,0;
13) 4,254; 9,32; 21,0; 22,0;
14) 5,184; 9,247; 22,0; 23,0;
15) 2,278; 6,251; 23,0; 24,0;
16) 1,60; 4,243; 24,0; 25,0;
17) 1,15; 8,308; 25,0; 26,0;
18) 3,118; 4,161; 26,0; 27,0;
19) 2,204; 7,87; 27,0; 28,0;
20) 1,301; 4,314; 28,0; 29,0;
21) 2,79; 7,268; 29,0; 30,0;
22) 4,57; 30,0; 31,0;
23) 2,249; 3,64; 31,0; 32,0;
24) 5,358; 32,0; 33,0;
25) 4,179; 8,32; 33,0; 34,0;
26) 2,180; 6,303; 34,0; 35,0;
27) 1,266; 4,344; 35,0; 36,0;
28) 3,237; 36,0; 37,0;
29) 2,79; 37,0; 38,0;
30) 2,250; 3,269; 38,0; 39,0;
31) 4,346; 39,0; 40,0;
32) 1,133; 3,251; 40,0; 41,0;
33) 1,341; 41,0; 42,0;
35) 2,46; 3,71; 43,0; 44,0;
36) 2,344; 3,46; 44,0; 45,0.

6. The system of claim 4, wherein for achieving maximum coding gain with coding rate 1/2, the SD-FEC LDPC decoder module is configured such that its sub-matrices that contain diagonals are arranged according to the following list, in which, each line represents a respective row of sub-matrices in the parity check matrix, and each pair of numbers within said each line corresponds to a sub-matrix within said respective parity check matrix row such that the first number in the pair indicates the sub-matrix ordinal number in the row and the second number indicates the shift of the sub-matrix diagonal from the diagonal location in an identity matrix of the same order:
1) 1,346; 3,184; 8,116; 9,133; 19,113; 21,0;
2) 6,209; 7,159; 11,239; 14,269; 21,0; 22,0;
3) 1,33; 2,201; 10,35; 16,124; 22,0; 23,0;
4) 1,155; 5,7; 9,151; 23,0; 24,0;
5) 2,327; 5,122; 20,216; 24,0; 25,0;
6) 3,280; 4,246; 14,181; 18,292; 25,0; 26,0;
7) 1,197; 5,254; 12,204; 17,293; 26,0; 27,0;
8) 5,138; 8,91; 15,144; 16,316; 27,0; 28,0;
9) 6,235; 7,228; 17,196; 19,58; 28,0; 29,0;
10) 2,284; 3,52; 11,160; 16,274; 29,0; 30,0;
11) 2,176; 3,108; 14,95; 15,231; 30,0; 31,0;
12) 4,46; 6,170; 13,297; 20,154; 31,0; 32,0;
13) 1,265; 4,81; 11,186; 14,306; 32,0; 33,0;
14) 1,72; 3,213; 10,76; 18,160; 33,0; 34,0;
15) 8,260; 12,183; 15,204; 17,118; 34,0; 35,0;
16) 7,284; 8,246; 16,286; 18,283; 35,0; 36,0;
17) 1,347; 2,179; 10,164; 19,196; 36,0; 37,0;
18) 1,49; 2,230; 10,296; 13,46; 37,0; 38,0;
19) 3,70; 4,262; 13,68; 18,358; 38,0; 39,0;
20) 2,215; 3,308; 12,342; 13,227; 39,0; 40,0;
21) 2,265; 7,54; 9,269; 19,135; 40,0; 41,0;
22) 2,83; 3,257; 12,15; 20,292; 41,0; 42,0;
23) 1,31; 3,95; 20,158; 42,0; 43,0;
24) 2,205; 3,175; 9,156; 15,228; 43,0; 44,0;
25) 1,137; 6,102; 11,329; 17,109; 44,0; 45,0.

7. The system of claim 4, wherein for achieving maximum coding gain with coding rate 3/4, the SD-FEC LDPC decoder module is configured such that its sub-matrices that contain diagonals are arranged according to the following list, in which, each line represents a respective row of sub-matrices in the parity check matrix, and each pair of numbers within said each line corresponds to a sub-matrix within said respective parity check matrix row such that the first number in the pair indicates the sub-matrix ordinal number in the row and the second number indicates the shift of the sub-matrix diagonal from the diagonal location in an identity matrix of the same order:
1) 1,185; 4,50; 7,337; 8,4; 9,246; 11,80; 14,253; 16,300; 20,308; 22,84; 26,23; 29,244; 33,14; 34,0;
2) 1,152; 2,97; 6,332; 8,184; 10,135; 15,307; 16,199; 23,236; 24,234; 27,4; 28,346; 34,0; 35,0;
3) 1,27; 2,279; 6,27; 9,42; 12,343; 15,347; 17,211; 21,39; 25,342; 27,150; 28,354; 35,0; 36,0;
4) 1,232; 3,38; 5,61; 8,52; 10,339; 18,231; 19,123; 21,257; 24,254; 29,308; 30,301; 36,0; 37,0;
5) 1,88; 2,325; 5,351; 11,288; 13,170; 19,91; 21,301; 25,225; 27,248; 29,315; 30,53; 33,215; 37,0; 38,0;
6) 1,334; 3,205; 6,217; 9,196; 12,49; 14,192; 18,318; 23,172; 24,55; 26,304; 28,24; 32,115; 38,0; 39,0;
7) 1,352; 3,50; 7,214; 8,288; 10,243; 14,297; 19,77; 20,137; 25,29; 26,357; 29,52; 32,154; 39,0; 40,0;
8) 1,309; 3,15; 5,29; 13,10; 15,2; 17,10; 19,355; 20,355; 22,41; 31,115; 33,259; 40,0; 41,0;
9) 1,213; 4,51; 5,91; 9,69; 10,113; 16,24; 17,238; 21,160; 23,260; 30,144; 31,343; 32,149; 41,0; 42,0;
10) 1,281; 4,205; 7,289; 11,253; 12,63; 16,312; 17,147; 22,163; 24,159; 26,113; 31,83; 42,0; 43,0;
11) 1,290; 4,332; 7,55; 12,159; 13,66; 14,147; 18,325; 22,188; 23,234; 27,153; 31,86; 33,170; 43,0; 44,0;
12) 1,323; 2,304; 6,289; 11,119; 13,223; 15,246; 18,16; 20,286; 25,358; 28,309; 30,148; 32,22; 44,0; 45,0.

8. The system of claim 4, wherein for achieving maximum coding gain with coding rate 5/6, the SD-FEC LDPC decoder module is configured such that its sub-matrices that contain diagonals are arranged according to the following list, in which, each line represents a respective row of sub-matrices in the parity check matrix, and each pair of numbers within said each line corresponds to a sub-matrix within said respective parity check matrix row such that the first number in the pair indicates the sub-matrix ordinal number in the row and the second number indicates the shift of the sub-matrix diagonal from the diagonal location in an identity matrix of the same order:
1) 2,121; 5,122; 6,326; 8,304; 9,165; 11,22; 14,331; 17,293; 20,287; 22,205; 26,115; 28,20; 31,221; 33,183; 35,14; 37,306; 38,0;
2) 3,215; 4,57; 7,176; 10,184; 11,237; 15,178; 21,262; 23,265; 25,312; 27,18; 30,77; 31,294; 35,269; 36,32; 37,4; 38,0; 39,0;
3) 2,212; 5,10; 7,82; 12,285; 16,224; 18,26; 20,321; 21,121; 23,73; 24,216; 26,52; 29,172; 30,80; 32,181; 34,329; 36,186; 39,0; 40,0; 1,33; 3,118; 8,57; 12,201; 13,203; 16,1; 18,272; 19,179; 22,285; 24,72; 26,287; 28,200; 30,135; 33,139; 35,239; 37,172; 40,0; 41,0;
4) 3,190; 4,155; 6,36; 10,108; 11,226; 15,356; 17,176; 19,221; 25,269; 26,273; 28,302; 29,254; 30,146; 33,33; 34,95; 36,325; 41,0; 42,0;
5) 1,48; 4,57; 7,210; 9,353; 13,205; 15,44; 17,337; 20,61; 23,89; 24,159; 27,255; 29,135; 31,89; 32,194; 35,116; 36,181; 42,0; 43,0;
6) 1,178; 8,335; 10,354; 12,271; 14,103; 16,120; 21,148; 23,27; 24,316; 25,109; 27,307; 29,339; 32,210; 33,281; 34,175; 37,222; 43,0; 44,0;
7) 2,241; 5,106; 6,329; 9,155; 13,350; 14,355; 18,303; 19,266; 22,355; 25,86; 27,348; 28,174; 31,354; 32,234; 34,203; 44,0; 45,0.

9. A method for achieving maximum coding gain while receiving DVB-S2 protocol data in a low-earth-orbit (LEO) communication satellite, wherein the satellite comprises a soft-decision forward error correction (SD-FEC) LDPC decoder module implemented in an application-specific integrated circuit (ASIC) module within a FEC encoder and decoder FPGA, the method comprising configuring the SD-FEC so as to apply to the received data a parity check matrix composed of 360×360 bit sub-matrices such that each sub-matrix is either a zero matrix, an identity matrix or a shifted diagonal identity matrix.

10. The method of claim 9, wherein, for achieving maximum coding gain with coding rate 1/4, the SD-FEC LDPC decoder module is configured such that the sub-matrices that contain diagonals are arranged according to the following list, in which, each line represents a respective row of sub-matrices in the parity check matrix, and each pair of numbers within said each line corresponds to a sub-matrix within said respective parity check matrix row such that the first number in the pair indicates the sub-matrix ordinal number in the row and the second number indicates the shift of the sub-matrix diagonal from the diagonal location in an identity matrix of the same order:
1) 2,162; 9,85; 10,0;
2) 2,172; 4,249; 10,0; 11,0;
3) 5,268; 11,0; 12,0;
4) 1,254; 4,195; 12,0; 13,0;
5) 1,247; 3,128; 13,0; 14,0;
6) 6,40; 14,0; 15,0;
7) 1,306; 3,74; 15,0; 16,0;
8) 4,212; 7,278; 16,0; 17,0;
9) 1,204; 3,48; 17,0; 18,0;
10) 3,220; 8,303; 18,0; 19,0;
11) 1,75; 3,342; 19,0; 20,0;
12) 1,23; 20,0; 21,0;
13) 4,254; 9,32; 21,0; 22,0;
14) 5,184; 9,247; 22,0; 23,0;
15) 2,278; 6,251; 23,0; 24,0;
16) 1,60; 4,243; 24,0; 25,0;
17) 1,15; 8,308; 25,0; 26,0;
18) 3,118; 4,161; 26,0; 27,0;
19) 2,204; 7,87; 27,0; 28,0;
20) 1,301; 4,314; 28,0; 29,0;
21) 2,79; 7,268; 29,0; 30,0;
22) 4,57; 30,0; 31,0;
23) 2,249; 3,64; 31,0; 32,0;
24) 5,358; 32,0; 33,0;
25) 4,179; 8,32; 33,0; 34,0;
26) 2,180; 6,303; 34,0; 35,0;
27) 1,266; 4,344; 35,0; 36,0;
28) 3,237; 36,0; 37,0;
29) 2,79; 37,0; 38,0;
30) 2,250; 3,269; 38,0; 39,0;
31) 4,346; 39,0; 40,0;
32) 1,133; 3,251; 40,0; 41,0;
33) 1,341; 41,0; 42,0;
34) 2,3; 4,102; 42,0; 43,0;
35) 2,46; 3,71; 43,0; 44,0;
36) 2,344; 3,46; 44,0; 45,0.

11. The method of claim 9, wherein for achieving maximum coding gain with coding rate 1/2, the SD-FEC LDPC decoder module is configured such that its sub-matrices that contain diagonals are arranged according to the following list, in which, each line represents a respective row of sub-matrices in the parity check matrix, and each pair of numbers within said each line corresponds to a sub-matrix within said respective parity check matrix row such that the first number in the pair indicates the sub-matrix ordinal number in the row and the second number indicates the shift of the sub-matrix diagonal from the diagonal location in an identity matrix of the same order:
1) 1,346; 3,184; 8,116; 9,133; 19,113; 21,0;
2) 6,209; 7,159; 11,239; 14,269; 21,0; 22,0;
3) 1,33; 2,201; 10,35; 16,124; 22,0; 23,0;
4) 1,155; 5,7; 9,151; 23,0; 24,0;
5) 2,327; 5,122; 20,216; 24,0; 25,0;
6) 3,280; 4,246; 14,181; 18,292; 25,0; 26,0;
7) 1,197; 5,254; 12,204; 17,293; 26,0; 27,0;
8) 5,138; 8,91; 15,144; 16,316; 27,0; 28,0;
9) 6,235; 7,228; 17,196; 19,58; 28,0; 29,0;
10) 2,284; 3,52; 11,160; 16,274; 29,0; 30,0;
11) 2,176; 3,108; 14,95; 15,231; 30,0; 31,0;
12) 4,46; 6,170; 13,297; 20,154; 31,0; 32,0;
13) 1,265; 4,81; 11,186; 14,306; 32,0; 33,0;
14) 1,72; 3,213; 10,76; 18,160; 33,0; 34,0;
15) 8,260; 12,183; 15,204; 17,118; 34,0; 35,0;
16) 7,284; 8,246; 16,286; 18,283; 35,0; 36,0;
17) 1,347; 2,179; 10,164; 19,196; 36,0; 37,0;
18) 1,49; 2,230; 10,296; 13,46; 37,0; 38,0;
19) 3,70; 4,262; 13,68; 18,358; 38,0; 39,0;
20) 2,215; 3,308; 12,342; 13,227; 39,0; 40,0;
21) 2,265; 7,54; 9,269; 19,135; 40,0; 41,0;
22) 2,83; 3,257; 12,15; 20,292; 41,0; 42,0;
23) 1,31; 3,95; 20,158; 42,0; 43,0;
24) 2,205; 3,175; 9,156; 15,228; 43,0; 44,0;
25) 1,137; 6,102; 11,329; 17,109; 44,0; 45,0.

12. The method of claim 9, wherein for achieving maximum coding gain with coding rate 3/4, the SD-FEC LDPC decoder module is configured such that its sub-matrices that contain diagonals are arranged according to the following list, in which, each line represents a respective row of sub-matrices in the parity check matrix, and each pair of numbers within said each line corresponds to a sub-matrix within said respective parity check matrix row such that the first number in the pair indicates the sub-matrix ordinal number in the row and the second number indicates the shift of the sub-matrix diagonal from the diagonal location in an identity matrix of the same order:
1) 1,185; 4,50; 7,337; 8,4; 9,246; 11,80; 14,253; 16,300; 20,308; 22,84; 26,23; 29,244; 33,14; 34,0;
2) 1,152; 2,97; 6,332; 8,184; 10,135; 15,307; 16,199; 23,236; 24,234; 27,4; 28,346; 34,0; 35,0;
3) 1,27; 2,279; 6,27; 9,42; 12,343; 15,347; 17,211; 21,39; 25,342; 27,150; 28,354; 35,0; 36,0;
4) 1,232; 3,38; 5,61; 8,52; 10,339; 18,231; 19,123; 21,257; 24,254; 29,308; 30,301; 36,0; 37,0;
5) 1,88; 2,325; 5,351; 11,288; 13,170; 19,91; 21,301; 25,225; 27,248; 29,315; 30,53; 33,215; 37,0; 38,0;
6) 1,334; 3,205; 6,217; 9,196; 12,49; 14,192; 18,318; 23,172; 24,55; 26,304; 28,24; 32,115; 38,0; 39,0;
7) 1,352; 3,50; 7,214; 8,288; 10,243; 14,297; 19,77; 20,137; 25,29; 26,357; 29,52; 32,154; 39,0; 40,0;
8) 1,309; 3,15; 5,29; 13,10; 15,2; 17,10; 19,355; 20,355; 22,41; 31,115; 33,259; 40,0; 41,0;
9) 1,213; 4,51; 5,91; 9,69; 10,113; 16,24; 17,238; 21,160; 23,260; 30,144; 31,343; 32,149; 41,0; 42,0;
10) 1,281; 4,205; 7,289; 11,253; 12,63; 16,312; 17,147; 22,163; 24,159; 26,113; 31,83; 42,0; 43,0;
11) 1,290; 4,332; 7,55; 12,159; 13,66; 14,147; 18,325; 22,188; 23,234; 27,153; 31,86; 33,170; 43,0; 44,0;
12) 1,323; 2,304; 6,289; 11,119; 13,223; 15,246; 18,16; 20,286; 25,358; 28,309; 30,148; 32,22; 44,0; 45,0.

13. The method of claim 9, wherein for achieving maximum coding gain with coding rate 5/6, the SD-FEC LDPC decoder module is configured such that its sub-matrices that contain diagonals are arranged according to the following list, in which, each line represents a respective row of sub-matrices in the parity check matrix, and each pair of numbers within said each line corresponds to a sub-matrix within said respective parity check matrix row such that the first number in the pair indicates the sub-matrix ordinal number in the row and the second number indicates the shift of the sub-matrix diagonal from the diagonal location in an identity matrix of the same order:
1) 2,121; 5,122; 6,326; 8,304; 9,165; 11,22; 14,331; 17,293; 20,287; 22,205; 26,115; 28,20; 31,221; 33,183; 35,14; 37,306; 38,0;
2) 3,215; 4,57; 7,176; 10,184; 11,237; 15,178; 21,262; 23,265; 25,312; 27,18; 30,77; 31,294; 35,269; 36,32; 37,4; 38,0; 39,0;
3) 2,212; 5,10; 7,82; 12,285; 16,224; 18,26; 20,321; 21,121; 23,73; 24,216; 26,52; 29,172; 30,80; 32,181; 34,329; 36,186; 39,0; 40,0; 1,33; 3,118; 8,57; 12,201; 13,203; 16,1; 18,272; 19,179; 22,285; 24,72; 26,287; 28,200; 30,135; 33,139; 35,239; 37,172; 40,0; 41,0;
4) 3,190; 4,155; 6,36; 10,108; 11,226; 15,356; 17,176; 19,221; 25,269; 26,273; 28,302; 29,254; 30,146; 33,33; 34,95; 36,325; 41,0; 42,0;
5) 1,48; 4,57; 7,210; 9,353; 13,205; 15,44; 17,337; 20,61; 23,89; 24,159; 27,255; 29,135; 31,89; 32,194; 35,116; 36,181; 42,0; 43,0;
6) 1,178; 8,335; 10,354; 12,271; 14,103; 16,120; 21,148; 23,27; 24,316; 25,109; 27,307; 29,339; 32,210; 33,281; 34,175; 37,222; 43,0; 44,0;
7) 2,241; 5,106; 6,329; 9,155; 13,350; 14,355; 18,303; 19,266; 22,355; 25,86; 27,348; 28,174; 31,354; 32,234; 34,203; 44,0; 45,0.
